(19) United States
(12) Patent Application Publication
(10) Pub. No.: US 2023/0208096 A1
(43) Pub. Date: Jun. 29, 2023

(54) RADIO FREQUENCY DEVICE FOR TRANSCEIVING MONITOR AND CONTROL SIGNALS FOR A LASER SOURCE

(71) Applicants: Nicholas S. Tomasello, Binghamton, NY (US); James P. Cioffi, Bayside, NY (US); Christopher L. Hancock, Chenango Forks, NY (US); David C. Brown, Friendsville, PA (US); Denis F. Nakazawa, Port Washington, NY (US)

(72) Inventors: Nicholas S. Tomasello, Binghamton, NY (US); James P. Cioffi, Bayside, NY (US); Christopher L. Hancock, Chenango Forks, NY (US); David C. Brown, Friendsville, PA (US); Denis F. Nakazawa, Port Washington, NY (US)

(21) Appl. No.: 18/064,533

(22) Filed: Dec. 12, 2022

Related U.S. Application Data
(60) Provisional application No. 63/266,103, filed on Dec. 28, 2021.

(51) Int. Cl. H01S 5/00; H01S 5/042; H01S 5/024; H01S 5/02212

(52) U.S. Cl. CPC H01S 5/0014; H01S 5/042; H01S 5/02415; H01S 5/02469; H01S 5/02212

(57) ABSTRACT

Systems, methods, and other embodiments for utilizing electrical and digital technologies for monitoring and controlling laser sources from an entirely separate location are disclosed. In particular, the present invention relates to using any radio frequency signal in conjunction with driving and control capabilities for application with TO-style laser diodes and TO-style solid-state laser devices of any, and all powers, currents, or voltages.

### CROSS-REFERENCE TO RELATED APPLICATION

This application claims priority to, and is a continuation-in-part of U.S. Patent Application 63/266,103, filed on Dec. 28, 2021, the disclosure of which is hereby incorporated by reference in its entirety to provide continuity of disclosure to the extent such disclosure is not inconsistent with the disclosure herein.

### FIELD OF THE INVENTION

The present invention discloses utilizing electrical and digital technologies for monitoring and controlling of laser sources from an entirely separate location. In particular, the invention relates to using any radio frequency signal in conjunction with driving and control capabilities for application with TO-style laser diodes and TO-style solid-state laser devices of any and all powers, currents, or voltages.

### BACKGROUND

Laser systems have continuously been developed with the ability to monitor and maintain values that are set by a user or technician for field and research applications. These signals all correspond with hardware needed such as cabling and wires in order to visualize these behaviors on a computer or separate device. It is normally comprised of a plug for communication that utilizes a human interface for real-time feedback and a plug for power that connects to the laser.

Currently, the only acceptable way to check on a laser system is through the constant interrogation conducted by an in-person (on-site) operator. This interrogation is required for situations such as biological applications to lasers, where activating bacteria needs to be monitored to maintain the experiment's integrity.

Other situations where eye safety is in question, also require an operator to be present to check on the laser system status. These statuses can deal with laser output power, laser operating temperature, and laser driving current, which can change over time due to the technology applied as well as cause catastrophic events to either experiment or the laser itself, or can even be life-threatening. These situations obviously cause the need for constant monitoring.

Currently in the industry, data logging and manipulation of a laser system is employed. These are all either design specific or require an expensive adoption to technology that can be applied in a certain setting, but do not give feedback about the entire system. This, in turn, requires further equipment to be used and higher-level software in order to have complete operation control.

Another problem with having to operate a laser system directly with the operator being located next to the laser system or through the use of cabling to connect the operator to the laser, is the need for an omnipresent operator to evaluate the system's conditions. This can cause problems in environments where it is either unfavorable or incapable of having a human presence. It also causes problems in situations that require long term logging and maintenance, and therefore indirectly requires the user of the laser system to not be present. This can be devastating to research in situations where power is lost and not noticed because no one is in the testing location and viewing the system.

Therefore, a need exists in both field and research applications for a novel radio frequency device and apparatus that is capable of monitoring and controlling various aspects of a laser system and can be visualized independently from an entirely separate location that is also accessible to the laser system operator both in proximity to the application and away from it. Additionally, a need exists to be able to monitor and control these laser systems in a fashion that can be accessible anywhere, such as a web service, so information can be interpolated and manipulated in any location with access to this web service. Finally, there is a need to operate a laser system of TO-type laser diode or TO-type solid state laser without the need of several incorporations of various machinery and be able to control all aspects of these style lasers from one point of contact and one point of operation.

### BRIEF SUMMARY OF THE INVENTION

This invention is a novel monitoring and controlling apparatus generally consisting of processing and transmission circuitry that allows interrogation of a laser system from a separate location. Interchangeable between different laser diodes and solid-state lasers, this apparatus offers a universal solution to conventional monitoring and human-based control schemes. The invention includes analog driving electronics for maintenance of temperature, current, and power, with digital signal conversion and communication to a web server-based application platform that is accessible from a separate computer or cellular phone. In preferred embodiments, the various features of the radio frequency (RF)-based wireless interrogation apparatus is able to control and measure information from any kind of laser source and can distinguish between each for optimal use.

### BRIEF DESCRIPTION OF THE DRAWINGS

Some embodiments of the present invention are illustrated as an example and are not limited by the figures of the accompanying drawings, in which like references may indicate similar elements and in which:

FIG. 1 depicts an exploded perspective view of one embodiment of an application for a radio frequency system for monitoring and controlling a laser source, according to various embodiments of the present invention.

FIG. 2 is an isometric view of the spring-loaded electrically conductive pins being located on the bottom of the laser diode casing, according to various embodiments of the present invention.

FIG. 3 shows a top view of an example of two circuit boards that can be made to make the radio frequency system for monitoring and controlling a laser source, according to various embodiments of the present invention.

FIG. 4 shows a bottom view of the example of two circuit boards that can be made to make the radio frequency system for monitoring and controlling a laser source, according to various embodiments of the present invention.

FIG. 5 depicts a computer screenshot view of one embodiment of a user interface platform used with the radio frequency system to monitor laser parameters, according to various embodiments of the present invention.

FIG. 6 is another embodiment of a screen shot showing a graph of laser data parameters over a period of time, according to various embodiments the present invention.

### DETAILED DESCRIPTION OF THE INVENTION

The terminology used herein is for the purpose of describing particular embodiments only and is not intended to be limiting of the invention. As used herein, the term “and/or” includes any and all combinations of one or more of the associated listed items. As used herein, singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Unless otherwise defined, all terms (including technical and scientific terms) used herein have the same meaning as commonly understood by one having ordinary skill in the art to which this invention belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

In describing the invention, it will be understood that a number of techniques and steps are disclosed. Each of these has individual benefits, and each can also be used in conjunction with one or more, or in some cases all, of the other disclosed techniques. Accordingly, for the sake of clarity, this description will refrain from repeating every possible combination of the individual steps in an unnecessary fashion. Nevertheless, the specification and claims should be read with the understanding that such combinations are entirely within the scope of the invention and the claims.

New radio frequency (RF) transmission and control technologies, devices, apparatuses, and methods for use with TO-style laser diodes and solid-state laser devices are discussed herein. In the following description, for purposes of explanation, numerous specific details are set forth in order to provide a thorough understanding of the present invention. It will be evident, however, to one skilled in the art that the present invention may be practiced without these specific details.

The present disclosure is to be considered an exemplification of the invention and is not intended to limit the invention to the specific embodiments illustrated by the figures or description below.

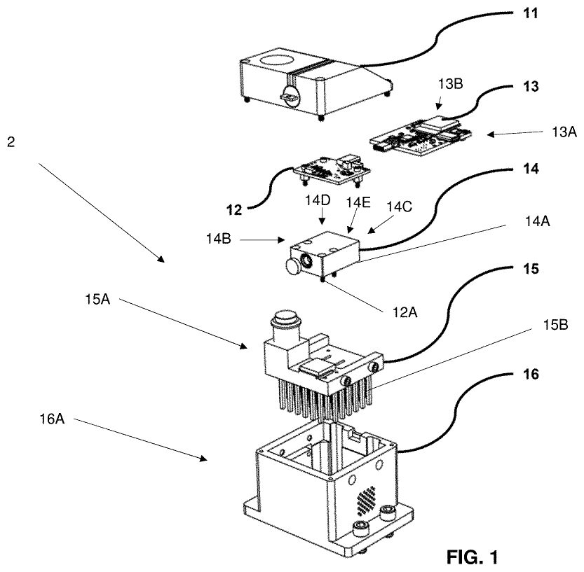

With respect to FIG. 1, there is illustrated one embodiment of an application for a radio frequency system 2 for monitoring and controlling a laser source, according to various embodiments of the present invention. As shown in FIG. 1, system 2 includes, in part, cap 11, primary driving circuit board 12, circuit board 13, laser diode assembly 14, heat sink assembly 15, and base housing 16.

The assembly of the system 2 includes screws, bolts, and fasteners that are used to attach aluminum heat sink assembly 15 (which are materials used to quickly conduct heat) and plastic (Polyamide 6) base housing 16. Preferably, machining is done on heat sink assembly 15 using a computer numerical control (CNC) or any other similar type of machining technique to cut the aluminum into the desired geometries for heatsinking of the laser diode assembly 14.

As shown in FIG. 1, system 2 includes, in part, elements that may comprise a radio frequency transceiver for use in monitoring and controlling system 2, according to various embodiments of the present invention. In one embodiment, system 2 is configured with a laser diode assembly 14, which is configured to mount onto both primary driving circuit board 12 and heat sink assembly 15. In particular, heat sink assembly 15 acts as the preferred embodiment of a heatsink for the generated heat from laser diode assembly 14, as will be discussed in greater detail later.

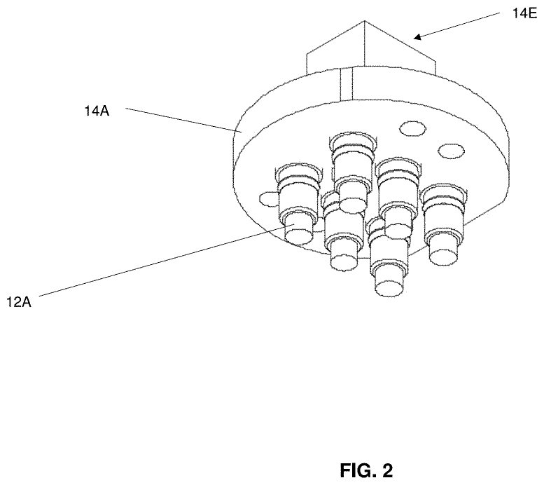

Furthermore, primary driving circuit board 12 is the preferred embodiment of the control apparatus of the laser diode assembly 14 and contacts laser diode assembly 14 through the use of spring-loaded electrically conductive pins 12A (FIG. 2). As shown in FIG. 2, spring-loaded electrically conductive pins 12A are conventionally attached to casing 14A of laser diode 14. Also, spring-loaded electrically conductive pins 12A are electrically connected to potentiometer 14E, located within laser diode assembly 14, as will be discussed in greater detail later. The combination of the primary driving circuit board 12, circuit board 13, laser diode assembly 14, and heat sink assembly 15 are inserted into casing 16. Cap 11 covers the rest of the components of system 2. A separate circuit board 13 is connected to primary driving circuit board 12 to provide the capabilities of processing and transmitting the signals for system 2.

Laser diode assembly 14, when stated, is meant to represent any manufactured semiconducting device that emits coherent light in a small form factor. In particular, laser diode assembly 14 is a conventional laser diode which includes, in part, a laser diode (not shown), which is manufactured by various companies (OSRAM as an example), a thermistor 14B which is a resistive device that changes resistance based on the temperature that it is exposed to, a photodetector 14C which is a device that collects light and can either be included in the laser diode's housing or is added to laser diode assembly 14 separately, a collimating lens (not shown) which is a lens that stops light particle divergence from the output facet of the laser diode, a focusing lens (not shown) which is a lens that takes a beam of light and directs it into a smaller point beam, and electromechanical actuators (not shown) that can change the spacing between each lens and the laser diode to change the beam quality and shape that exits the laser diode assembly 14. The thermistor 14B is glued and placed on the backside of the laser diode to offer a signal to the system 2 in order to regulate the temperature of the laser diode assembly 14 in that vicinity. This is necessary to prevent overheating of the laser diode assembly 14 as well as controlling the local temperature of laser diode assembly 14 in order to change lasing wavelength and power.

It is to be further understood that laser diode assembly 14 can include either laser diodes or solid-state laser devices that fit a form factor of a TO-style package that is mountable and connectable electronically/mechanically for heatsinking and turning it on in a controlled manner. This is because these laser devices have sensory components such as photodetection, beam shape detection by another type of pixelated photodetector, temperature detection, temperature control effort such as a thermoelectric cooler or other means of chilling/heating the device, optical elements for beam shaping (such as collimation, focusing, or beam prism steering) which require motional control through any kind of motor apparatus and feedback for the position of them either by encoding or distance measurement or electronic triggering. All these factors can either be used or not used, mounted or not mounted, and connected/disconnected while still allowing use of the other components. This is especially the case for situations where photodetection or beam detection is desired as a sub-system without an internal laser for the use with other systems outside of this one. There can also be multiple of these systems.

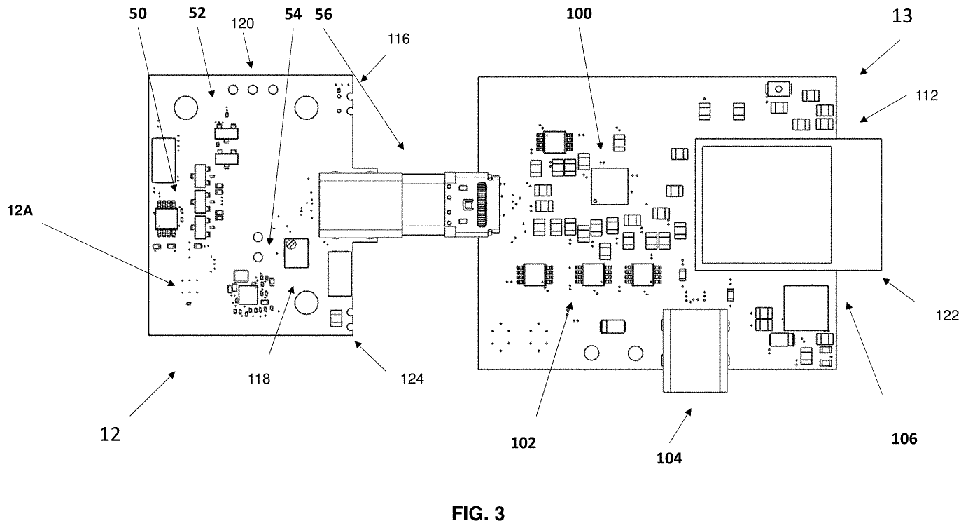

Regarding heat sink assembly 15, it is necessary for the heatsinking aspect of this system, where due to all the chilling/heating and temperature management of laser diode assembly 14, the energy sometimes needs to be dissipated/absorbed to/from another location. Since the heat sink assembly 15 extracts/inserts the heat energy from all the components mentioned in laser diode assembly 14, a convective heat removal/inclusion is needed underneath the heat sink assembly 15, and the devices, which can either include fans or pumps 16A in casing 16 for air or water/alcohol energy dissipation/absorption. This can also be replaced with more conductive heat transfer approaches, but the current technology is designed to include convective means. These fans/pumps 16A are controlled by analog means and have sensors for flow rates which are sent and given to by the Analog to Digital/Digital to Analog converter (ADC/DAC) 100 (FIG. 3).

In one embodiment, a secondary circuit board 13 is fitted onto laser diode assembly 14 that connects the photodetector 14C, thermistor 14B, laser diode, and optical actuators of the laser diode assembly 14 to the primary driving circuit board 12. In another embodiment, the secondary circuit board 13 also includes a resistor 14D on it that is selective depending on the laser diode placed into laser diode assembly 14.

A unique aspect of the present invention is that this resistor 14D is the shunting resistor of the circuit in series with the laser diode assembly 14. This structure is necessary so that driving signals sent by the radio frequency controller 50 will not send too much current to the laser diode assembly 14 and damage the laser diode assembly 14. The resistor 14DA is different for each different type of laser assembly since they require different amounts of current. Another unique aspect of the present invention is that the resistor 14D can be utilized with primary driving circuit board 12 for any laser assembly without worrying about operating parameters and prevention of damage to laser diode assembly 14.

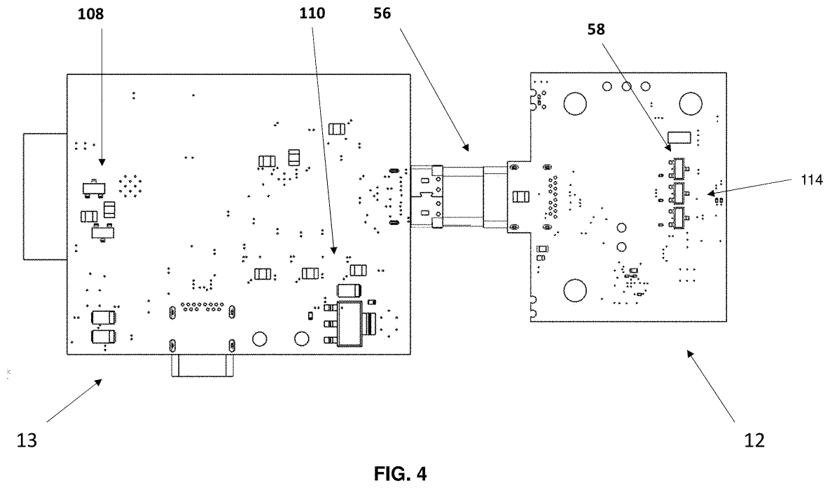

With respect to FIGS. 3 and 4, the elements of the system 2 that configure the transceiver, monitor, and control system 2 are automatic current controller 50 for laser diode assembly 14, temperature stability management assembly 52 for the cascaded MOSFETs, PID controller 54 for TEC 15A and thermistor 14B (FIG. 1) for the temperature of laser diode assembly 14, USB-C connector 56 for signal contacts, ADC/DAC 100 (it is to be understood that in some embodiments, no DAC is included), buffer circuits 102 for signals, USB-C connector 104 for computer interfacing and flashing processor, and processor, flashing utility, and RF antenna electronics 106 for computation and linking wireless connections to the web service.

In particular, automatic current controller 50 is an example of a preferred embodiment of an automatic, analog current driver circuit on a circuit board that maintains constant current based on the operation of the indicator from the preferred embodiment of the laser diode assembly 14. In one embodiment, the processing circuit 13 includes operational amplifiers 112 and feedback mechanisms that smooth signals by filtering and other noise suppression approaches.

The temperature of the laser is controlled using temperature stability management assembly 52, designed to be used with a thermoelectric cooler 15A and thermistor 14B with PID controller 54. All of this is powered and connected to circuit board 13 via USB-C connector 56, which is the preferred embodiment of the plug and port for the signal channeling and power using a universal serial bus C type, in the present invention.

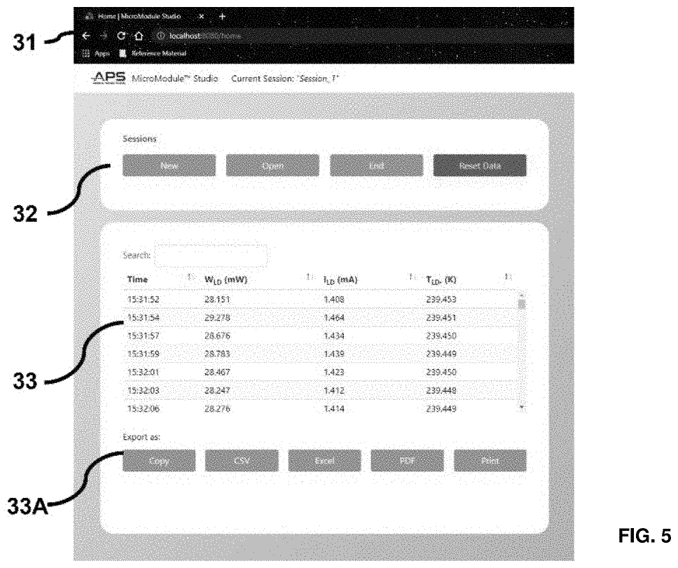

In one embodiment, signals that flow through USB-C connector 56 are received by ADC/DAC 100 to be converted from an analog to a digital representation of each of the signals. Although only analog to digital conversion is shown, it is obvious to one skilled in the art that digital to analog conversion can also be included in this device. Because of this, the invention and device are explained with the notion that both digital to analog, and analog to digital conversion schemes can be performed. These conversions are then communicated to processor, flashing utility, and RF antenna electronics 106 for computation and linking wireless connections to the web service and a user interface (FIG. 5) using a serial peripheral interface (SPI). Because of the nature of the preferred embodiment of the processor, flashing utility, and RF antenna electronics 106, a preferred embodiment of a radio frequency transceiver 122 is embedded and connected to processor, flashing utility, and RF antenna electronics 106 to allow signal propagation over the air to a web server using a preferred communication method of hypertext transfer protocol. An example of a protocol used to create a preferred embodiment of a back-end interface, Django®, was established to receive and send the signals from system 2 to both a remote device associated with a user and a preferred embodiment of a web application.

Regarding the driver electronics of the diode laser assembly 14, this includes the analog circuitry for the laser control electronics. Here, signals are sent and received to/from the ADC/DAC 100 to provide a control reference and create a control effort to maintain that reference with error feedback from the laser diode assembly 14 to maintain stability. Current flowing through the laser diode assembly 14 needs to be stable initially without signals sent or received, which is done in the present invention. The power of the laser diode assembly 14 is then controlled by the sent and received signals by either increasing or decreasing the current to increase or decrease the power.

Regarding the control electronics of the motor and optical components of laser diode assembly 14, this includes the analog circuitry for the optical and motor control electronics of laser diode assembly 14. Here, signals are sent and received to/from ADC/DAC 100 to provide a control reference and create a control effort to maintain that reference with error feedback from devices in laser diode assembly 14 to maintain stability. This includes the optics for collimation, focusing, or beam prism steering and the motors to move these optics, as well as the photodetector 14C (i.e., pixelated photo-detecting camera) that is the feedback for the laser diode assembly 14. This beam signal information is transported through the cloud or hardline to show the user the current beam parameters for alteration by the motion of the optics or a closed loop control to alter the optics for a desired beam parameter, as will be discussed in greater detail later. The motors are controlled through conventional stability based analog driving and sensing of motors such as rotary, servo, brushless, or even piezo-based motors.

Regarding temperature control electronics, this includes the analog circuitry for the temperature control electronics for controlling the temperature of laser diode assembly 14. Here, signals are sent and received to/from ADC/DAC 100 to provide a control reference and create a control effort to maintain that reference with error feedback from laser diode assembly 14 to maintain stability. This involves thermistors 14B for measuring current temperature and the temperature control effort of either chilling or heating. In the present invention, this is done using thermoelectric coolers 15A (FIG. 1) and PID (proportional, integral, derivative) controller 54 to provide extremely precise and smooth temperature stabilization, as will be discussed in greater detail later. However, it is to be understood that conventional temperature stability methods can also be used in this aspect of system 2.

With reference to FIG. 3, the secondary board 13 makes contact with primary driving circuit board 12 through spring-loaded electrical pieces 12A that connect each signal to the rest of the circuit on primary driving circuit board 12. Besides this, laser diode assembly 14 rests on a thermoelectric cooler (TEC) 15A that is silver epoxied to heat sink assembly 15 in the same location as the laser diode assembly 14.

A unique aspect of the present invention is that this thermoelectric cooler 15A is the other aspect of the thermistor or temperature circuit, acting as the control effort of the circuit to maintain desired temperature settings. In particular, on primary driving circuit board 12, a temperature-controlling circuit is directly associated with an integrated circuit (IC). An integrated circuit is meant as a manufactured circuit chip with microstructures created within it to provide an entire circuit system within a small footprint. This IC, along with various passive components such as resistors, inductors, and capacitors, creates a proportional integral derivative (PID) controller 54 to maintain temperature based on a set point.

Another unique aspect of the present invention is that the stability of this PID controller 54 is developed by a repetitive process of changing the P, I, and D gains of controller 54 from a dithering or modulating tone applied on an evaluation module provided by analog devices. This is tuned until a perfect step response is realized without any oscillations. After tuning, the chosen passive elements that allow for that specific gain are applied to the system of the IC. This tuning allows any laser diode to be incorporated into laser diode assembly 14 without having to change any of the PID gains, since the heat transfer characteristics stay the same (from resistor 14D to laser diode to an outer aluminum casing 14A on laser diode assembly 14 to TEC 15A to heat sink assembly 15).

Another unique aspect of the present invention is that although other systems utilize only PI, ID, PD, or others, using a PID controller 54 offers one example of a means for stable temperature control of system 2. Since a TEC 15A is used to remove heat from the laser diode assembly 14, excess heat is dissipated onto the bottom heat sink assembly 15. To remove this energy from system 2 entirely, in one embodiment, dual fans 16A (FIG. 1) were chosen as one means to convectively cool the heat sink assembly 15 and allow further heat dissipation.

These fans 16A are conventionally mounted internally onto the base housing 16 and powered through filtering of the power source provided by primary driving circuit board 12. The fans 16A are connected to primary driving circuit board at hook-up connection 124. Another unique aspect of the present invention is that heat sink assembly 15 has a geometry of extended pins 15B on its lower side to allow more surface area for convection to remove heat from the heat sink assembly 15.

It is to be understood that there are various methods and avenues for controlling a laser diode's power and current. In one embodiment of the present invention, however, a combination of operational amplifiers and bipolar junction/amplifying transistors (BJT) and MOSFETs are used to provide a variety of gain and power depending on the utilized laser diode. A cascaded network of MOSFETs 114 allows for a wide variety of driving currents of these lasers without dissipating too much heat on the circuit board. This architecture requires that the BJTs regulate the current going through each MOSFET to be equal, thereby ultimately needing a current source to operate the BJTs correctly based on their inherent bandgap as a function of temperature. With the inclusion of other passive components like capacitors and resistors for filtering the power and signals throughout the circuit, the present invention provides a very clean and smooth automatic current-controlling apparatus that can be applied to any laser diode using the secondary circuit board 12 within laser diode assembly 14. With a power push button switch 116, a potentiometer 14E (FIG. 2) to change laser current, a potentiometer 118 for changing laser operating temperature, and copper-plated holes 120 on the circuit board to probe and measure the parameters of system 2, most of the system 2 can be operated as a stand-alone unit without the need for digital counterparts and only require minimal user interaction. The present invention, however, utilizes these various features in tandem with system 2, allowing access and control of system 2 from an external point or separate location using radio frequency technology.

It is to be understood that with any approach to receiving analog signals and sending information to analog drivers, there is a requirement for all of this to convert between analog and digital domains. By providing correct grounding planes, digital/analog separation, and passive filtering of the signals, the ADC/DAC 100 can connect to these signals to send the information to any processor through various digital communication protocols. In its preferred embodiment, a USB-C type connector 56 was chosen to send the information to allow many channels to pass between system 2 and devices used to interact with system 2 to monitor and/or control system 2 so that a lot of information can be sent and received. This structure is not limited; other connectors, such as RS232 or DB-type plugs, can be used. A conventional ADC integrated circuit was chosen, which receives analog signals, converts them into a digitally addressed piece of information, and sends the converted signals to a processor through a communication peripheral such as an SPI.

Conversely, a conventional DAC integrated circuit receives addressed communications via the SPI from a processor and then sends analog driving signals to the primary driving circuit board 12. It is understood that this is not limited to only SPI and can preferably be done through other forms of communication, such as I2C. This setup allows the present invention to include multiple laser diodes, laser diode current drivers, laser diode temperature controllers, optical collimator actuators, optical focusing lens actuators, and any other peripheral sensory signal into the system 2 with separated and continual control/monitoring of each apparatus and aspect all using one processor.

Regarding USB-C type connector 56, it is to be understood that USB-C type connector 56 can be used as an alternate form of signal transmission if the wireless aspect is not desired. In one embodiment, an application for this would be at a secure facility or location where cyber security over the air is an issue. The same program can be operated with a wired connection instead of a wireless one all through the universal serial bus.

Regarding the ADC/DAC 100, this aspect of the present invention is used to convert analog signals and digital signals between the interface to use the data for control and monitoring system 2. It requires conventional integrated circuit technology and a high degree of filtering for noise and glitch mitigation. This converter acts as the bridge between the analog and digital counterparts. They can be cascaded to include multiple of these. They can all operate on the same digital channel for communication to the process and radio frequency technology without altering the processing and requiring more sophisticated computer architecture, such as an operating system, as will be discussed in greater detail later.

In one embodiment of the present invention, a processing IC (ESP32-WROOM-32E) was used to process the ADC monitoring information, send the driving information through the DAC, and then the rest of the system 2. This integrated circuit was chosen because it includes the WiFi transmission IEEE 802.11b/g/n standard and an integrated radio frequency antenna for ease of integration with the web service and system 2. It is to be understood that without this integrated circuit, an example of an avenue for a designer to incorporate WiFi transmission would be using several different integrated circuits. This could be done, especially considering the availability of components and situations requiring a customized design, but for ease of designing system 2, the ESP32 was chosen.

In order to send information using the IEEE 802.11b/g/n standard and WiFi, hypertext transfer protocol was chosen to connect system 2 to a conventional web service. In particular, the host service uses a conventional protocol, a python-based coding platform that allows ease of integration of system 2 with a conventional web design. Furthermore, this platform allows the creation of a framework for a website that can communicate between various IP addresses (which is a unique string of characters that identifies each device using the Internet protocol to communicate over a network), such as system 2 communicating to the conventional central servicing routine.

Regarding the signal data aspect of the present invention, it is to be understood that this aspect encompasses any and all forms of data communication. Some examples include WiFi, LTE, “5G”, and protocols used to communicate in a legible format for comprehension by other entities that get stored in a momentary or consistent database depending on the user application. This is the route for both sending and receiving between system 2 and the peripheral widgets of system 2, which are being monitored and/or controlled.

Furthermore, the present invention has both processing and RF concepts built into one system 2, but they can be separated. This takes in all the information from the ADC/DAC 100 and sends this information to either the USB-C type connector 56 or over the air (i.e., wireless) to eventually get to a signal database via the signal data, as will be discussed in greater detail later. It also does the reverse, where information is sent to it and channeled through system 2 to the analog components to adjust parameters according to the user or a control loop, as will be discussed in greater detail later. It is to be understood that this can be any processor component and any RF communication frequency that is allowable, as long as there is enough bandwidth for the data to pass and the processor can communicate to ADC/DAC 100 correctly. This component can also be designed with a custom approach or bought off the shelf, depending on the application or use case/nature of the use of the present invention.

Regarding the signal database, it is understood that this is where the signal data is stored. In the wireless setting, the signal data is conventionally stored on the Internet via the conventional web service, which is bought at a fee and developed with the security of the information. This also represents the case where a software program developed for use on a particular platform or device (native application) is used, in which case a web service is not used, and the data is locally stored.

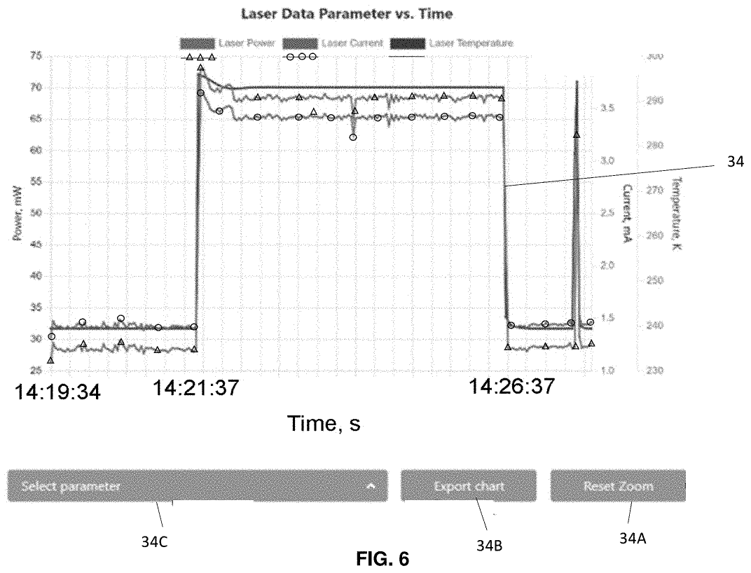

Regarding the web URL or the native application, it is to be understood that this is the end result of system 2, where all of the signals and controls for laser diode assembly 14 are displayed and accessible by the user with a graphical user interface that is either hosted through a company-controlled web service with encrypted data navigation or locally through an engineered interface that is not connected to the Internet, as will be discussed in greater detail later (FIGS. 5 and 6).

By implementing the above-identified protocol, a separate conventional protocol is used to create a front-end application that provides a user experience according to one embodiment of the present invention. This front-end application communicates with the information provided by the conventional protocol, a python-based coding platform, and allocates it to various graphs and tables that can be accessible to the user with ease and intuition.

In another embodiment of the present invention, user's remote device (such as a smartphone, tablet, desktop, or other similar communication device) can be used to establish a user interface that can be utilized as a user registration which can be established on the website and with a known IP address based on what is purchased so that the information from the user's device gets sent directly to the user's page and various signals can be seen. In one embodiment, this webpage is accessible to both laptops and cellular devices and can also have the ability to be turned into an application on these devices. All the data is logged with time stamps that can be changed based on the user-selected sampling rate of the information. This data can be exported into various file types to be converted into figures and tables of the user's choosing.

A unique aspect of the present invention is that operating conditions of system 2, such as laser power, current, and temperature, can all be monitored throughout an experiment or procedure. Furthermore, optical, electrical, and mechanical conditions of system 2 can all be controlled throughout an experiment or procedure as well with the ability to do so from a variety of locations and distances. With encryption, the remote device can be handled in a secure manner and only accessible by the user's identification.

In one embodiment of the present invention, a front-end user application of system 2 can be seen with respect to FIGS. 5 and 6. Although there is a plethora of ways to create something like this, the chosen method for this preferred embodiment was established using a combination of HTML, CSS, and JavaScript, all operated by a preferred JavaScript framework of Vue.js and located in this example on a local host 31 (FIG. 5). Another method might be the “MERN” technology stack, which is a conglomeration of web application development platforms consisting of the MongoDB, Express, React, and Node.js web development technologies.

In FIG. 6, a user can see various representations of the signals that could be chosen to be monitored and controlled and have several interface feature options. To start, the application can begin through 32 with a variety of opening, reset, and closing features with the click of a button. The interface in this chosen representation has data received and sent via a table 33 and a chart 34, with feature options for each. Parameters can be selected for both table 33 and chart 34 using reset zoom button 34A, which color codes the signals chosen and adds them to table 33. Reset zoom button 34A allows the user to take a closer or expanded view of each preferred embodiment of a signal. The user also has the option to download this information from export as buttons 33A and export chart button 34B to convert into various exemplifications of this information (FIG. 6). Drop down menu 34C shows the parameter that was selected and displayed in FIG. 6. This user interface provides a means for a user to access the laser diode assembly 14 and control or monitor its features totally remotely and separate from the system itself.

Regarding the front-end user application of system 2, this represents either user-based monitoring or control or potential processing of the data for the user to select a parameter such as beam shape or power and the system changing reference points and information to achieve the desired parameter by checking the monitored signals. This represents the ability to either feedforward or feedback the data depending on the user application.

A unique aspect of the present invention is that system 2 can be utilized in the following manners:
1. Multiple Laser Devices can be operated at the same time and monitored/controlled simultaneously
2. Add Power Detection Circuitry to monitor/control output power of laser
   a. Change of temperature or current to change laser power
3. Add pixelated monitoring technology to measure beam profile information of laser
   a. Optically control or alter beam shape through piezo driving stages
4. Add modulation technology to send chosen waveforms through system
5. Measure spectral information of the laser output
6. Ambient temperature measurements
7. Wirelessly Turn the laser on or off

While it has not been mentioned, one familiar with the art would realize that system 2 is not limited by the materials used to create each apparatus that comprises the invention. Any other material type can be chosen to comprise some or all of the elements of the radio frequency transceiver for the laser systems device and apparatus in various embodiments of the present invention.

Although the present invention has been illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present invention, are contemplated thereby, and are intended to be covered by the following claims.

What is claimed is:

1. A radio frequency-based monitor and controller system for use with lasers, comprising:
a laser assembly;
a first circuit board operatively connected to the laser assembly and configured to control the laser assembly,
wherein the first circuit board includes operational amplifiers, integrated circuits, and amplifying transistors; and
a second circuit board operatively connected to the first circuit board and configured to process and transmit electronic signals from the system,
wherein the second circuit board includes an analog to digital/digital to analog converter, a radio frequency amplifier, and a radio frequency transceiver.

2. The system, according to claim 1, wherein the system further comprises:
a heat sink assembly operatively connected to the laser assembly;
a housing located adjacent to the heat sink assembly; and
a cap located adjacent to the first and second circuit boards.

3. The system, according to claim 1, wherein the first circuit board further comprises:
an analog laser current controller;
an analog laser temperature controller; and
a plurality of spring-loaded electrically conductive pins.

4. The system, according to claim 2, wherein the heat sink assembly further comprises:
a thermoelectric cooler operatively connected to the heat sink assembly and located adjacent to the laser assembly.

5. The system, according to claim 4, wherein the laser assembly further comprises:
at least one thermistor configured to measure a current temperature of the laser assembly, wherein the at least one thermistor is electrically connected to the analog to digital/digital to analog converter; and
a photodetector configured to detect a light beam being produced by the laser assembly, wherein the photodetector is electrically connected to the analog to digital/digital to analog converter.

6. The system, according to claim 5, wherein the first circuit board further comprises:
a proportional integral derivative (PID) controller electrically connected to the thermoelectric cooler and the at least one thermistor, wherein the PID controller is configured to maintain a desired temperature of the laser assembly.

7. The system, according to claim 1, wherein the system, further comprises:
a user interface electrically connected to the laser assembly, wherein the user interface is configured to access the laser assembly and control or monitor features of the laser assembly remotely.

8. A laser system, comprising:
a laser assembly;
a first circuit board operatively connected to the laser assembly and configured to control the laser assembly,
wherein the first circuit board includes operational amplifiers, integrated circuits, and amplifying transistors; and
a second circuit board operatively connected to the first circuit board and configured to process and transmit electronic signals from the system,
wherein the second circuit board includes an analog to digital/digital to analog converter, a radio frequency amplifier, and a radio frequency transceiver.

9. The system, according to claim 8, wherein the system further comprises:
a heat sink assembly operatively connected to the laser assembly;
a housing located adjacent to the heat sink assembly; and
a cap located adjacent to the first and second circuit boards.

10. The system, according to claim 8, wherein the first circuit board further comprises:
an analog laser current controller;
an analog laser temperature controller; and
a plurality of spring-loaded electrically conductive pins.

11. The system, according to claim 9, wherein the heat sink assembly further comprises:
a thermoelectric cooler operatively connected to the heat sink assembly and located adjacent to the laser assembly.

12. The system, according to claim 11, wherein the laser assembly further comprises:
at least one thermistor configured to measure a current temperature of the laser assembly, wherein the at least one thermistor is electrically connected to the analog to digital/digital to analog converter; and
a photodetector configured to detect a light beam being produced by the laser assembly, wherein the photodetector is electrically connected to the analog to digital/digital to analog converter.

13. The system, according to claim 12, wherein the first circuit board further comprises:
a proportional integral derivative (PID) controller electrically connected to the thermoelectric cooler and the at least one thermistor, wherein the PID controller is configured to maintain a desired temperature of the laser assembly.

14. The system, according to claim 8, wherein the system, further comprises:
a user interface electrically connected to the laser assembly, wherein the user interface is configured to access the laser assembly and control or monitor features of the laser assembly remotely.

15. A method of constructing a radio frequency-based monitor and controller system for use with lasers, comprising:
providing a laser assembly;
attaching a first circuit board to the laser assembly, wherein the first circuit board is configured to control the laser assembly and wherein the first circuit board includes operational amplifiers, integrated circuits, and amplifying transistors; and
attaching a second circuit board to the first circuit board,
wherein the second circuit board is configured to process and transmit electronic signals from the system and wherein the second circuit board includes an analog to digital/digital to analog converter, a radio frequency amplifier, and a radio frequency transceiver.

16. The method, according to claim 15, wherein the method further comprises:
attaching a heat sink assembly to the laser assembly;
locating a housing adjacent to the heat sink assembly; and
attaching a cap to the housing in order to enclose the laser assembly, the first and second circuit boards, and the heat sink assembly within the housing and the cap.

17. The method, according to claim 15, wherein the first circuit board further comprises:
providing an analog laser current controller;
providing an analog laser temperature controller; and
providing a plurality of spring-loaded electrically conductive pins.

18. The method, according to claim 16, wherein the heat sink assembly further comprises:
attaching a thermoelectric cooler to the heat sink assembly, wherein the thermoelectric cooler is also located adjacent to the laser assembly.

19. The method, according to claim 18, wherein the laser assembly further comprises:
providing at least one thermistor that is configured to measure a current temperature of the laser assembly, wherein the at least one thermistor is electrically connected to the analog to digital/digital to analog converter; and
providing a photodetector that is configured to detect a light beam being produced by the laser assembly, wherein the photodetector is electrically connected to the analog to digital/digital to analog converter.

20. The system, according to claim 15, wherein the system, further comprises:
providing a user interface, wherein the user interface is configured to be electrically connected to the laser assembly, and wherein the user interface is configured to access the laser assembly and control or monitor features of the laser assembly remotely.
